(19) United States
(12) Patent Application Publication
(10) Pub. No.: US 2024/0249962 A1
(43) Pub. Date: Jul. 25, 2024

(54) SUBSTRATE PROCESSING APPARATUS, METHOD OF PROCESSING SUBSTRATE, METHOD OF MANUFACTURING SEMICONDUCTOR DEVICE, AND RECORDING MEDIUM

(71) Applicant: Kokusai Electric Corporation, Tokyo (JP)

(72) Inventors: Hideharu ITATANI, Toyama-shi (JP); Naofumi Ohashi, Toyama-shi (JP)

(73) Assignee: Kokusai Electric Corporation, Tokyo (JP)

(21) Appl. No.: 18/402,814

(22) Filed: Jan. 3, 2024

(30) Foreign Application Priority Data
Jan. 19, 2023 (JP) 2023-006849

(51) Int. Cl. H01L 21/67; H01L 21/687

(52) U.S. Cl. CPC H01L 21/67259; H01L 21/67109; H01L 21/68764

(57) ABSTRACT

A technique includes a process chamber where a substrate-processing process including a heating process to a substrate is capable of being performed, a boat configured to support the substrate, a revolution part including a plurality of boat supports configured to support the boat, and capable of revolving the boat supports, a delivery chamber including a first area arranged below the process chamber, a second area where the substrate after the heating process is capable of waiting, and a third area where the substrate is capable of being delivered to and from an adjacent transfer chamber, among areas above the revolution part, a cooler capable of performing a cooling process to the substrate in the second area, and a controller capable of controlling a revolution operation or a movement operation.

### CROSS-REFERENCE TO RELATED APPLICATION

This application is based upon and claims the benefit of priority from Japanese Patent Application No. 2023-006849, filed on Jan. 19, 2023, the entire contents of which are incorporated herein by reference.

### TECHNICAL FIELD

The present disclosure relates to a substrate processing apparatus, a method of processing a substrate, a method of manufacturing a semiconductor device, and a recording medium.

### BACKGROUND

In the related art, as one example of a substrate processing apparatus used in a semiconductor device manufacturing process, for example, an apparatus is known in which a plurality of boats is arranged in a transfer chamber. The boat arranged in the transfer chamber is moved to a process chamber above the transfer chamber. A substrate-processing process including a heating process is performed in the process chamber. Thereafter, the boat is returned to the transfer chamber where a cooling process is performed.

It is conceivable that the excess waiting time of substrates increases depending on the end time of the substrate-processing process including the heating process of the substrates in the process chamber and the end time of the cooling process of the substrates in the transfer chamber.

### SUMMARY

Some embodiments of the present disclosure provide a technique capable of reducing the excess waiting time of substrates in a substrate-processing process.

According to one embodiment of the present disclosure, there is provided a technique that includes: a process chamber where a substrate-processing process including a heating process to a substrate is capable of being performed; a boat configured to support the substrate; a revolution part including a plurality of boat supports configured to support the boat, and capable of revolving the boat supports; a delivery chamber including a first area arranged below the process chamber, a second area where the substrate after the heating process is capable of waiting, and a third area where the substrate is capable of being delivered to and from an adjacent transfer chamber, among areas above the revolution part; a cooler capable of performing a cooling process to the substrate in the second area; and a controller capable of controlling a revolution operation of revolving the substrate from the second area to the third area by the revolution part, or a movement operation of moving the substrate from the process chamber to the first area, such that the revolution operation or the movement operation is to be performed depending on a difference between an end time of the substrate-processing process to the substrate in the process chamber and an end time of the cooling process to the substrate in the second area.

### BRIEF DESCRIPTION OF DRAWINGS

The accompanying drawings, which are incorporated in and constitute a part of the specification, illustrate embodiments of the present disclosure.

FIG. 1 is a sectional view showing a schematic configuration example of a substrate processing apparatus according to an embodiment of the present disclosure.

FIG. 2 is a vertical sectional view showing the configuration example of the substrate processing apparatus according to the embodiment of the present disclosure.

FIG. 3A is an explanatory diagram showing an example of a schematic configuration of a first gas supplier included in a reactor shown in FIG. 2.

FIG. 3B is an explanatory diagram showing an example of a schematic configuration of a second gas supplier included in the reactor shown in FIG. 2.

FIG. 3C is an explanatory diagram showing an example of a schematic configuration of a third gas supplier included in the reactor shown in FIG. 2.

FIG. 4 is a diagram showing a configuration of a controller of the substrate processing apparatus according to an embodiment of the present disclosure.

FIG. 5A is an explanatory diagram illustrating an operation of a revolution part of the substrate processing apparatus according to an embodiment of the present disclosure.

FIG. 5B is an explanatory diagram illustrating an operation of the revolution part of the substrate processing apparatus according to an embodiment of the present disclosure.

FIG. 5C is an explanatory diagram illustrating an operation of the revolution part of the substrate processing apparatus according to an embodiment of the present disclosure.

FIG. 5D is an explanatory diagram illustrating an operation of the revolution part of the substrate processing apparatus according to an embodiment of the present disclosure.

FIG. 5E is an explanatory diagram illustrating an operation of the revolution part of the substrate processing apparatus according to an embodiment of the present disclosure.

FIG. 6A is an explanatory diagram illustrating another example of an operation of the revolution part of the substrate processing apparatus according to an embodiment of the present disclosure.

FIG. 6B is an explanatory diagram illustrating another example of an operation of the revolution unit in the substrate processing apparatus according to an embodiment of the present disclosure.

FIG. 6C is an explanatory diagram illustrating another example of an operation of the revolution part of the substrate processing apparatus according to an embodiment of the present disclosure.

FIG. 7 is a flowchart showing a substrate-processing process according to an embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments according to the present disclosure will be described below with reference to the drawings. The drawings used in the following description are all schematic, and the dimensional relationship of respective elements, the ratio of respective elements, and the like in the drawings do not necessarily match the real ones. Even between a plurality of drawings, the dimensional relationship of respective elements, the ratio of respective elements, and the like do not necessarily match.

### (1) Configuration of Substrate Processing Apparatus

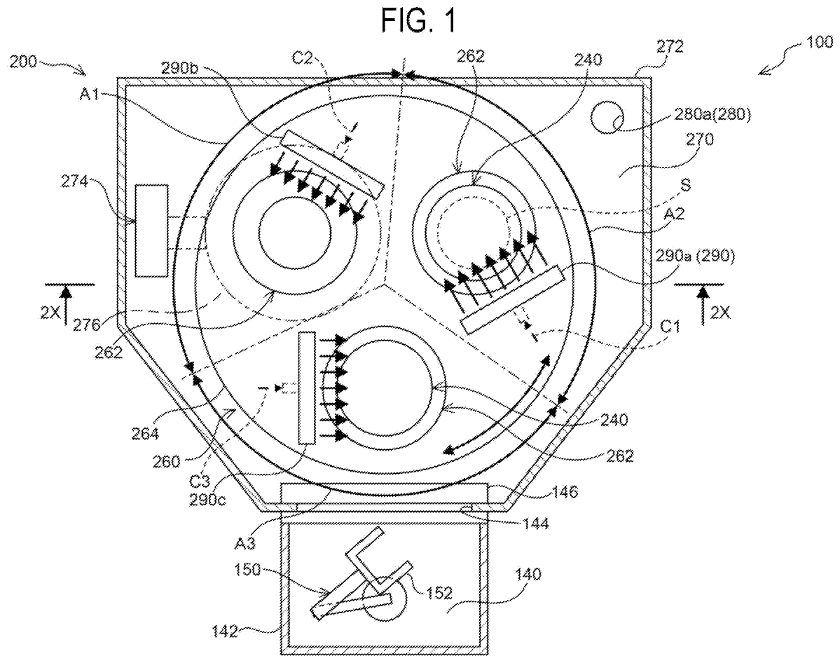

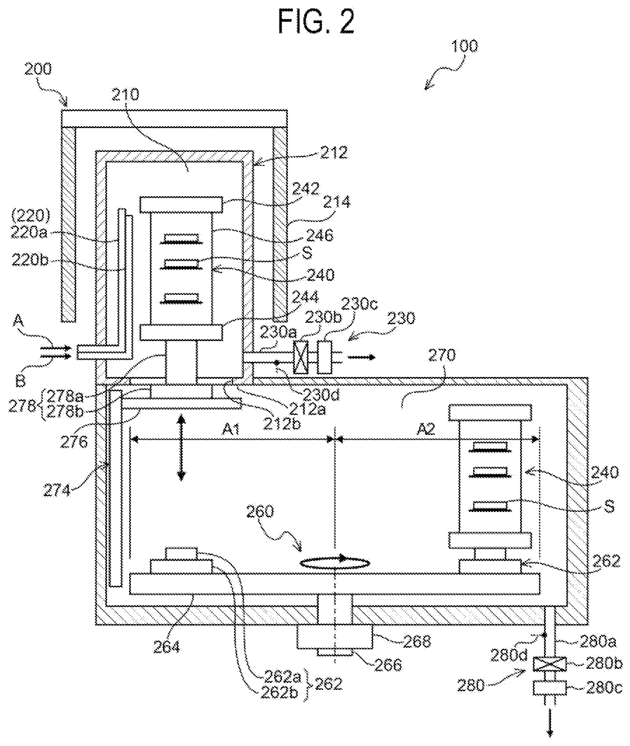

A schematic configuration of a substrate processing apparatus according to an embodiment of the present disclosure will be described with reference to FIGS. 1 and 2. FIG. 1 is a sectional view showing a schematic configuration example of a substrate processing apparatus according to the present technique. FIG. 2 is a vertical sectional view showing the schematic configuration example of the substrate processing apparatus according to the embodiment of the present disclosure, and is a sectional view taken along arrow 2X-2X in FIG. 1.

FIGS. 1 and 2 show a substrate processing apparatus 100 to which the technique of the present disclosure is applied. The substrate processing apparatus 100 is an apparatus that processes a substrate S. The substrate processing apparatus 100 includes a transfer chamber 140 and a reactor 200.

### <Transfer Chamber 140>

The transfer chamber 140 is a chamber in which the substrate S is transferred under negative pressure. The transfer chamber 140 is configured by a housing 142. Although not shown, a vacuum device is connected to the transfer chamber 140 to keep the inside of the chamber under negative pressure. This vacuum device sets the inside of the transfer chamber 140 to negative pressure.

The transfer chamber 140 is configured to communicate with a delivery chamber 270 included in the reactor 200. Specifically, the transfer chamber 140 communicates with the delivery chamber 270 through a loading/unloading port 144 installed at a housing 272 that constitutes the delivery chamber 270. The loading/unloading port 144 is used as a passage for loading the substrate S from the transfer chamber 140 into the delivery chamber 270 or for unloading the substrate S from the delivery chamber 270 to the transfer chamber 140. The loading/unloading port 144 is opened and closed by a gate valve 146 installed at the housing 272.

A transfer robot 150 that delivers (transfers) the substrate S under negative pressure is installed in the transfer chamber 140. The transfer robot 150 includes an arm 152 including an end effector. The transfer robot 150 is configured to be moved up and down and rotated by a lifting device (not shown) and a rotating device (not shown) while maintaining the airtightness of the transfer chamber 140.

The transfer robot 150 receives the substrate S before being processed by the reactor 200 from a device outside the transfer chamber 140, and loads the received substrate S into the delivery chamber 270 in the reactor 200. Further, the transfer robot 150 unloads the substrate S after being processed by the reactor 200 from the delivery chamber 270, and delivers the unloaded substrate S to a device outside the transfer chamber 140. In this embodiment, the substrate S before being processed by the reactor 200 is referred to as an unprocessed substrate S. Further, the substrate S after being subjected to processes (a heating process and a cooling process) by the reactor 200 is referred to as a processed substrate S.

### <Reactor 200>

The reactor 200 is a device that is capable of processing the substrate S. The reactor 200 is, for example, a device that performs processes such as forming a thin film on the surface of the substrate S, and the like.

The reactor 200 includes a process chamber 210, a boat 240, a revolution part 260, a delivery chamber 270, a cooler 290, and a controller 400. The process chamber 210 is located above the delivery chamber 270. Here, the term “upper” refers to the upper side in the vertical direction. Further, the term “lower” refers to the lower side in the vertical direction. Moreover, the vertical direction in the embodiment is the same as the up-down direction of the substrate processing apparatus 100. Hereinafter, the upper side and the lower side in the vertical direction will be simply referred to as “upper” and “lower”.

### (Process Chamber 210)

The process chamber 210 is a chamber in which substrate-processing process including a process of heating the substrate S can be performed. This process chamber 210 is mainly composed of a reaction tube 212. A heater 214 as a heating part that heats the process chamber 210 via the reaction tube 212 is arranged at the outer peripheral side of the reaction tube 212. The heater 214 is spaced apart from the outer peripheral wall of the reaction tube 212. In this embodiment, a resistance heater is used as the heater 214. The heater 214 may be a heater other than the resistance heater as long as it can heat the process chamber 210.

The upper end of the reaction tube 212 is closed. A flange portion 212a that protrudes radially inward of the reaction tube 212 is installed at the lower end of the reaction tube 212. The center of the flange portion 212a is opened to form a furnace opening 212b. A boat 240 moves between the process chamber 210 and the delivery chamber 270 through the furnace opening 212b.

The reaction tube 212 is configured to be capable of accommodating the boat 240 that supports the substrate S. In the internal space of the reaction tube 212, a region where the boat 240 that supports the substrate S is accommodated is called a processing region, and a section that constitutes the processing region is called a process chamber 210.

A plurality of nozzles 220 is installed in the reaction tube 212. These nozzles 220 penetrate the peripheral wall of the reaction tube 212 and extend from the lower side to the upper side. A plurality of gas holes (not shown) spaced apart in the extension direction thereof is installed at each nozzle 220. The gas supplied from the gas holes of the nozzle 220 is supplied to the substrates S supported on the boat 240 in the process chamber 210.

The nozzle 220 is provided for each type of gas, for example. In this embodiment, two nozzles 220a and 220b are used as an example. The respective nozzles 220 are arranged so as not to overlap in the horizontal direction.

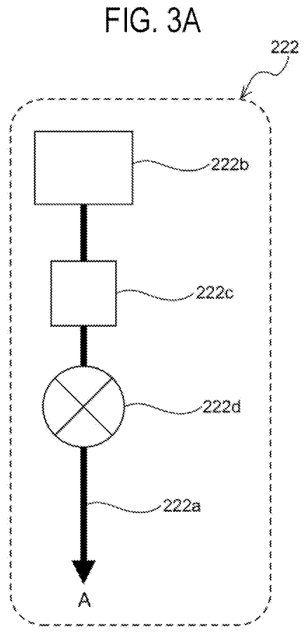

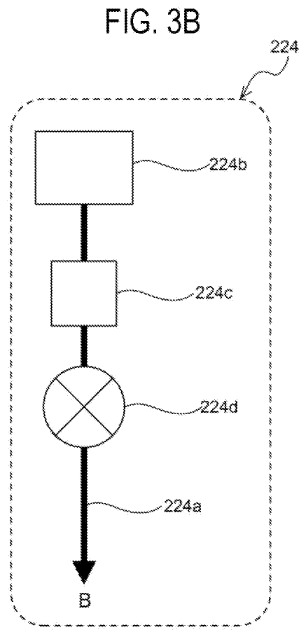

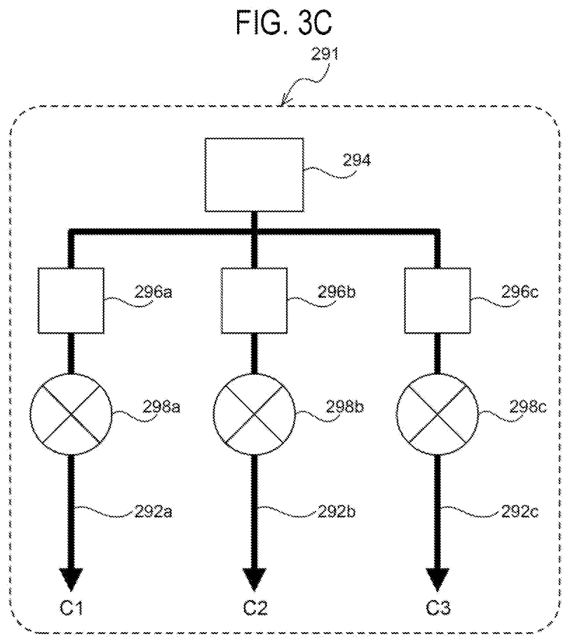

As shown in FIG. 3A, a first gas is supplied from a first gas supplier 222 to the nozzle 220a. That is, the first gas supplier 222 is configured to supply the first gas to the nozzle 220a. The first gas supplier 222 includes a gas supply pipe 222a, a first gas source 222b, a mass flow controller (MFC) 222c as a flow rate controller (flow rate control part), and a valve 222d as an opening/closing valve. The first gas source 222b, the MFC 222c, and the valve 222d are installed at the gas supply pipe 222a in this order from the upstream side. The gas supply pipe 222a is configured to communicate with the nozzle 220a.

The first gas source 222b is a source of the first gas containing a first element (also referred to as “first-element-containing gas”). The first-element-containing gas is one of precursor gases, i.e., processing gases. In this regard, the first element is, for example, silicon. Specifically, the first-element-containing gas is a chlorosilane precursor gas containing Si—Cl bonds, such as a hexachlorodisilane (Si₂Cl₆, abbreviation: HCDS) gas, a monochlorosilane (SiH₃Cl, abbreviation: MCS) gas, a dichlorosilane (SiH₂Cl₂, abbreviation: DCS) gas, a trichlorosilane (SiHCl₃, abbreviation: TCS) gas, a tetrachlorosilane (SiCl₄), abbreviation: STC) gas, an octachlorotrisilane (Si₃Cl₈, abbreviation: OCTS) gas, or the like. The first gas supplier 222 is also referred to as a silicon-containing gas supplier.

As shown in FIG. 3B, a second gas is supplied from a second gas supplier 224 to the nozzle 220b. That is, the second gas supplier 224 is configured to supply the second gas to the nozzle 220b. The second gas supplier 224 includes a gas supply pipe 224a, a second gas source 224b, an MFC 224c, and a valve 224d. The second gas source 224b, the MFC 224c, and the valve 224d are installed at the gas supply pipe 224a in this order from the upstream side. The gas supply pipe 224a is configured to communicate with the nozzle 220b.

The second gas source 224b is a source of the second gas containing a second element (hereinafter also referred to as “second-element-containing gas”). The second-element-containing gas is one of the processing gases. The second-element-containing gas may be considered as a reaction gas or a modifying gas.

In this regard, the second-element-containing gas contains a second element different from the first element. The second element is, for example, one of oxygen (O), nitrogen (N), and carbon (C). In this embodiment, the second-element-containing gas is, for example, a nitrogen-containing gas. Specifically, the second-element-containing gas is a hydrogen nitride-based gas containing an N—H bond, such as an ammonia (NH₃) gas, a diazene (N₂H₂) gas, a hydrazine (N₂H₄) gas, an N₃H₈ gas or the like. The second gas supplier 224 is also referred to as a reaction gas supplier.

In this embodiment, the number of nozzles 220 is two, but the present disclosure is not limited to this configuration. The number of nozzles 220 may be set to three or more depending on the content of a substrate-processing process.

As shown in FIG. 2, an exhauster 230 is connected to the reaction tube 212. The exhauster 230 is a device that evacuates the inside of the reaction tube 212 to a predetermined pressure (degree of vacuum). The exhauster 230 includes an exhaust pipe 230a, a valve 230b, an APC (Auto Pressure Controller) valve 230c as a pressure regulator (pressure regulation part), and a vacuum pump (not shown). The exhaust pipe 230a communicates with the inside of the reaction tube 212. The vacuum pump is connected to the exhaust pipe 230a via the valve 230b and the valve 230c. Further, a pressure detector 230d having a function of detecting the pressure inside the reaction tube 212 may be installed at the exhauster 230. The pressure inside the reaction tube 212 is adjusted by the cooperation of the gas supplier described above and the exhauster 230. When regulating the pressure, for example, the pressure value detected by the pressure detector 230d may be regulated to a predetermined value.

### (Boat 240)

The boat 240 is a support tool capable of supporting substrates S. The boat 240 is configured to be able to support a plurality of substrates S at intervals in the vertical direction. The boat 240 includes a top plate portion 242, a bottom plate portion 244, and a support portion 246. The support portion 246 is located between the top plate portion 242 and the bottom plate portion 244. Further, the support portion 246 includes a plurality of mounting portions (not shown) that can support a plurality of substrates S at intervals in the vertical direction. In other words, the support portion 246 can support a plurality of substrates S in multiple stages in the vertical direction using the plurality of mounting portions.

### (Revolution Part 260)

As shown in FIG. 1, the revolution part 260 is a device that can revolve the boat 240. The revolution part 260 includes boat supports 262, a revolution table 264, a revolution shaft 266, and a revolution mechanism 268.

The boat supports 262 are portions that support boats 240. A plurality of boat supports 262 are installed at the revolution table 264. Specifically, the boat supports 262 are installed at intervals in the rotation direction of the revolution table 264. In this embodiment, as an example, three boat supports 262 are installed at the revolution table 264. Each of the boat supports 262 includes a rotary shaft 262a and a rotation mechanism 262b. The rotary shaft 262a extends in the vertical direction from the revolution table 264. The upper end of the rotary shaft 262a is releasably connected to the bottom plate portion 244 of the boat 240. If the rotary shaft 262a rotates with the bottom plate portion 244 connected to the upper end of the rotary shaft 262a, the boat 240 is rotated with respect to the revolution table 264. For example, the orientation of the boat 240 can be adjusted by rotating the boat 240 when the substrate S is transferred by the transfer robot 150. The rotation mechanism 262b is fixed to the revolution table 264 to rotatably support the rotary shaft 262a.

The boat supports 262 are provided on the upper surface of the revolution table 264. The revolution shaft 266 is connected to the center of the revolution table 264. The rotation of the revolution shaft 266 causes the revolution table 264 to rotate. The rotation of the revolution table 264 causes the boat supports 262 to revolve around the revolution shaft 266.

The revolution shaft 266 is connected to the revolution table 264. The revolution shaft 266 extends in the vertical direction and passes through the bottom wall of the delivery chamber 270. The revolution shaft 266 rotates the revolution table 264 by rotational force from the revolution mechanism 268, and causes the boat supports 262 to revolve. The revolution mechanism 268 is controlled by a controller 400, which will be described later.

The revolution mechanism 268 is installed at the lower surface of the bottom wall of the delivery chamber 270 to rotatably support the revolution shaft 266. For example, by rotating the revolution table 264, the boat 240 is moved from a position adjacent to the loading/unloading port 144 to below the process chamber 210. Specifically, when moving to the next area, the revolution table 264 is rotated so that the boats can revolve about 120 degrees depending on a situation.

### (Delivery Chamber 270)

As shown in FIG. 2, the delivery chamber 270 is a chamber in which the substrate S can be delivered by the transfer robot 150 of the transfer chamber 140 via the loading/unloading port 144. The delivery chamber 270 is located below the process chamber 210 and is configured to communicate with the process chamber 210. Specifically, the lower end of the reaction tube 212 is connected to the upper portion (ceiling) of the housing 272 that constitutes the delivery chamber 270. The delivery chamber 270 communicates with the inside of the reaction tube 212 via the furnace operation 212b.

A loading/unloading port 144 for loading/unloading the substrate S is installed at the side wall of the housing 272. The loading/unloading port 144 is opened and closed by a gate valve 146. In the delivery chamber 270, mounting the substrate S onto the boat 240 through the loading/unloading port 144 by the transfer robot 150, or taking out the substrate S from the boat 240 by the transfer robot 150 is performed.

A boat elevator 274 is installed in the delivery chamber 270. The boat elevator 274 is a device that can raise and lower the boat 240. The boat elevator 274 includes a lid 276 that supports the boat 240. The boat 240 moves between the delivery chamber 270 and the process chamber 210 as the lid 276 is raised and lowered. The lid 276 is a member that closes the furnace opening 212b. Due to this, the diameter of the lid 276 is set to be larger than the diameter of the furnace opening 212b. An O-ring as a sealing member may be installed on the lower surface of the flange portion 212a of the reaction tube 212 or on the upper surface of the lid 276. If the O-ring is installed, when the boat 240 is set at a predetermined position in the process chamber 210, the O-ring is squashed and deformed between the flange portion 212a and the lid 276. By this the inside of the reaction tube 212 is maintained more airtightly. Further, a heater may be installed at the lid 276. By installing the heater at the lid 276, it is possible to maintain the temperature of the substrates S disposed in the lower portion of the boat 240 and the temperature of the substrates S disposed in the upper portion of the boat 240 equally.

The boat support 278 that supports the boat 240 is installed on the lid 276. The boat support 278 includes a rotary shaft 278a and a rotation mechanism 278b. The rotary shaft 278a extends in the vertical direction. The bottom plate portion 244 of the boat 240 is connected to the upper end of the rotary shaft 278a. If the rotary shaft 278a rotates with the bottom plate portion 244 of the boat 240 connected to the upper end of the rotary shaft 278a, the boat 240 is rotated relative to the lid 276. For example, the boat 240 accommodated in the process chamber 210 is rotated due to the rotation of the rotary shaft 278a. Further, the rotation mechanism 278b is fixed to the lid 276. The rotation mechanism 278b rotatably supports the rotary shaft 278a.

The boat elevator 274 moves the lid 276 downward to receive the boat 240 from the boat support 262 on the revolution part 260 at the upper end of the rotary shaft 278a. If the boat elevator 274 receives the boat 240, it raises the lid 276. Then, the boat 240 is accommodated in the process chamber 210. Further, after the substrate-processing process to the substrate S in the process chamber 210 is completed, the boat elevator 274 lowers the lid 276 and takes out the boat 240 from the process chamber 210. Then, the boat 240 is delivered from the rotary shaft 278a over the lid 276 to the boat support 262 on the revolution part 260.

An exhauster 280 is connected to the delivery chamber 270. The exhauster 280 is a device that evacuates the transfer chamber 270 so that the pressure within the delivery chamber 270 reaches a predetermined pressure (degree of vacuum). The exhauster 280 includes an exhaust pipe 280a, a valve 280b, an APC valve 280c, and a vacuum pump (not shown). The exhaust pipe 280a communicates with the delivery chamber 270. The vacuum pump is connected to the exhaust pipe 280a via the valve 280b and the valve 280c. Further, a pressure detector 280d having a function of detecting the pressure in the delivery chamber 270 is installed at the exhauster 280.

As shown in FIG. 1, the delivery chamber 270 includes a first area A1, a second area A2, and a third area A3 in the area above the revolution part 260. The first area A1 and the second area A2 are also shown in FIG. 2.

The first area A1 is an area where the boat 240 can be moved between the revolution part 260 and the boat elevator 274. Specifically, in the first area A1, the boat 240 is moved between the boat support 262 of the revolution part 260 and the boat support 278 of the boat elevator 274. The first area A1 is arranged below the process chamber 210. Furthermore, the first area A1 includes at least the furnace opening 212b when viewed from above.

The second area A2 is an area where the substrate S after a heating process can be kept on standby. The second area A2 is also an area where the substrate S after the heating process can be subjected to a cooling process. Specifically, in the second area A2, an inert gas is sent from a cooler 290 toward the substrate S after the heating process. Thus, the substrate S after the heating process is cooled. The second area A2 is disposed downstream of the first area A1 in the rotation direction when the revolution part 260 rotates clockwise (rightward).

The third area A3 is adjacent to the transfer chamber 140, and is an area where the substrate S can be transferred to and from the transfer chamber 140. Specifically, the transfer robot 150 delivers an unprocessed substrate S to the boat 240 located in the third area A3, and receives a processed substrate S from the boat 240 located in the third area A3. In this way, the substrate S is transferred between the third area A3 and the transfer chamber 140. In the third area A3, the boat 240 is arranged at a position facing the loading/unloading port 144, and is configured such that the transfer robot 150 can transfer the substrate S thereto.

In this embodiment, as shown in FIG. 1, for the sake of convenience, the first area A1, the second area A2, and the third area A3 are areas divided at equal angles (120 degrees) and centered on the rotation axis of the revolution part 260. That is, the first area A1, the second area A2, and the third area A3 are set to have the same size. The present disclosure is not limited to this configuration. The size of each area may be set as appropriate. Moreover, an area different from the first area A1, the second area A2, and the third area A3 may be newly set.

### (Cooler 290)

As shown in FIG. 1, the cooler 290 is a device capable of cooling the substrate S after the heating process. In this embodiment, an inert gas is sent to the substrate S from the cooler 290 to cool the substrate S.

The cooler 290 is arranged in the delivery chamber 270. Specifically, a plurality of coolers 290 are arranged over the revolution table 264 of the revolution part 260 at intervals in the rotation direction of the revolution table 264. In this embodiment, for example, three coolers 290 are arranged near the three boat supports 262 of the revolution part 260, respectively. The cooler 290 is configured to supply an inert gas to the boat 240 supported by the boat support 262. The cooler 290 is provided with gas holes, and the inert gas supplied to the cooler 290 is sent to the substrates S supported by the boat 240 through the gas holes.

As shown in FIG. 3C, an inert gas is supplied from a third gas supplier 291 to the respective coolers 290. The third gas supplier 291 includes gas supply pipes 292a, 292b and 292c, a third gas source 294, MFCs 296a, 296b and 296c, and valves 298a, 298b and 298c. The third gas source 294, the MFC 296a, and the valve 298a are installed at the gas supply pipe 292a in this order from the upstream side. The gas supply pipe 292a is configured to communicate with the cooler 290a among the three coolers 290. The third gas source 294, the MFC 296b, and the valve 298b are installed at the gas supply pipe 292b in this order from the upstream side. The gas supply pipe 292b is configured to communicate with the cooler 290b among the three coolers 290. The third gas source 294, the MFC 296c, and the valve 298c are installed at the gas supply pipe 292c in this order from the upstream side. The gas supply pipe 292c is configured to communicate with the cooler 290c among the three coolers 290. Examples of the inert gas supplied from the third gas source 294 include a nitrogen (N₂) gas and the like.

### <Controller>

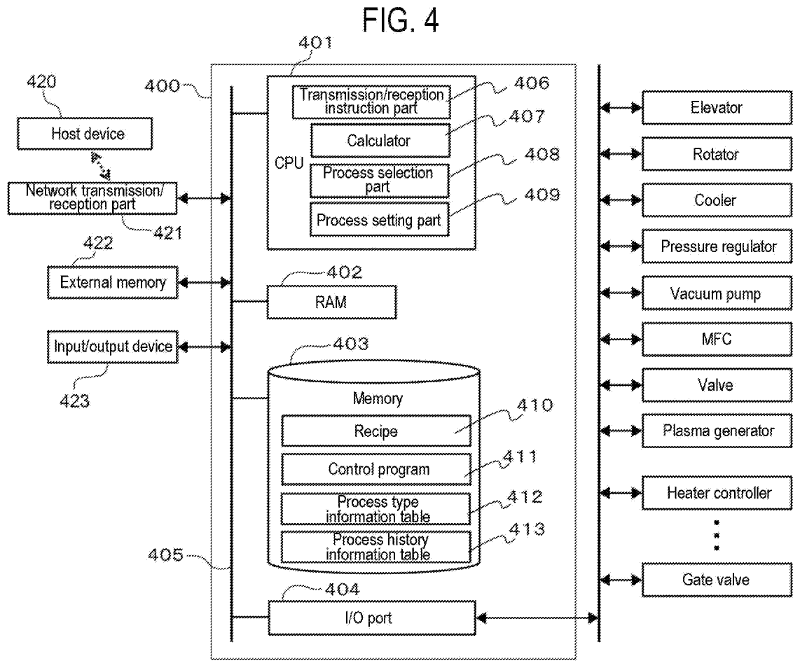

Next, the controller 400 will be described with reference to FIG. 4. The controller 400 controls the operation of each part of the substrate processing apparatus 100.

The controller 400, which is a control part (control means), is configured as a computer including a CPU (Central Processing Unit) 401, a RAM (Random Access Memory) 402, a memory 403 as a memory device, and an I/O port 404. The RAM 402, the memory 403, and the I/O port 404 are configured to be able to exchange data with the CPU 401 via an internal bus 405. Transmission and reception of data within the substrate processing apparatus 100 are performed according to instructions from a transmission/reception instruction part 406, which is one of the functions of the CPU 401. Further, calculations in the substrate processing apparatus 100 are performed by a calculator 407, which is one of the functions of the CPU 401. Moreover, the selection of each operation in the substrate processing apparatus 100 is performed by the selection of a process selection part 408, which is one of the functions of the CPU 401. In addition, the setting for each operation in the substrate processing apparatus 100 is performed by the selection of a process setting part 409, which is one of the functions of the CPU 401.

The CPU 401 is configured to read a control program from the memory 403 and execute the control program, and is configured to read a process recipe from the memory 403 in response to the input of an operation command from an input/output device 423 or the like. The CPU 401 is configured to be able to control, for example, the opening/closing operation of the gate valve 146, the on/off control of each pump, the flow rate adjustment operation of the MFC, the opening/closing operation of the valves, and the like in accordance with the contents of the process recipe thus read.

The memory 403 includes, for example, a flash memory, an HDD (Hard Disk Drive), or the like. The memory 403 readably stores a recipe 410 consisting of a process recipe in which procedures and conditions for a substrate-processing process are described, and the like, a control program 411 for controlling the operation of the substrate processing apparatus, a process type information table 412 in which the types of substrate-processing processes are stored, a process history table 413 in which the history of a substrate-processing process is recorded, and so forth.

The process recipe functions as a program, and is combined to cause the controller 400 to execute each procedure in a below-described substrate-processing process to obtain a predetermined result.

Hereinafter, the process recipe, the control program, and the like will be collectively and simply referred to as programs. When the word “programs” is used in this specification, it may include only a process recipe, only a control program, or both. In addition, the RAM 402 is configured as a memory area (work area) in which programs, data, and the like read by the CPU 401 are temporarily held.

The I/O port 404 is connected to respective components such as the gate valve 146, each pressure regulator, each pump, the heater controller, and the like. Furthermore, a network transmission/reception part 421 is installed which is connected to a host device 420 via a network.

The controller 400 according to the present disclosure may be configured by installing the program into a computer using an external memory 422 that stores the program described above. The external memory 422 includes, for example, a magnetic disk such as a hard disk or the like, an optical disk such as a DVD or the like, a magneto-optical disk such as an MO or the like, and a semiconductor memory such as a USB memory or the like. Further, the means for supplying the program to the computer is not limited to supplying the program via the external memory 422. For example, the program may be supplied by using communication means such as the Internet or a dedicated line not via the external memory 422. The memory 403 and the external memory 422 are configured as computer-readable recording medium. Hereinafter, these will be collectively referred to as a recording medium. In this specification, when the term “recording medium” is used, it may include only the memory 403, only the external memory 422, or both.

Next, the operation of transferring the substrate S in the delivery chamber 270 under the control of the controller 400 will be described.

The controller 400 can control a revolution operation of revolving the substrate S from the second area A2 to the third area A3 by the revolution part 260, or a movement operation of moving the substrate from the process chamber 210 to the first area A1, where the revolution operation or the movement operation is to be performed according to a difference between the end time of the substrate-processing process to the substrate S in the process chamber 210 and the end time of the cooling process to the substrate S in the second area A2. In this regard, the revolution operation of revolving the substrate S from the second area A2 to the third area A3 refers to an operation of moving the substrate S, which has been cooled in the second area A2, to the third area A3 by the revolution of the revolution part 260. Furthermore, the movement operation of moving the substrate from the process chamber 210 to the first area A1 refers to an operation of moving the substrate S, which has been subjected to a substrate-processing process including a heating process in the process chamber 210, to the first area A1. The substrate S moved from the process chamber 210 to the first area A1 are then moved to the second area A2. That is, the controller 400 moves the substrate S, which has been moved from the process chamber 210 to the first area A1, and to the second area A2.

The substrate-processing process includes a loading process of loading the substrate S into the process chamber 210, a heating process of heating the substrate S in the process chamber 210, and a movement preparation process of preparing movement of the substrate S after the heating process, from the process chamber 210 to the delivery chamber 270. That is, the end time of the substrate-processing process to the substrate S is the time at which the movement preparation process is completed. Further, the movement preparation process refers to, for example, a process of bringing the pressure inside the reaction tube 212 close to the pressure in the delivery chamber 270 when moving the substrate S from the process chamber 210 to the delivery chamber 270. The loading process is performed in a state in which the inside of the process chamber 210 is heated. That is, the substrate S sent from the first area A1 are accommodated in the heated process chamber 210.

In this embodiment, if the end time of the cooling process is earlier than the end time of the substrate-processing process, the controller 400 controls the revolution operation to be performed without unloading the substrate S from the process chamber 210. In particular, if the time required for the substrate S to move from the second area A2 to the third area A3 is smaller than the difference between the end time of the substrate-processing process and the end time of the cooling process, the controller 400 controls the revolution operation to be performed.

Moreover, the controller 400 controls the revolution operation to be performed if there is no substrate S to be newly subjected to a heating process.

The substrate S subjected to the heating process is cooled in the second area A2 by an inert gas sent from the cooler 290. Specifically, the substrate S taken out from the process chamber 210 is kept in a waiting state in the second area A2, and is cooled by the inert gas sent from the cooler 290. If the substrate S is not waiting in the second area A2, the controller 400 controls the supply amount of the cooling gas to be smaller than the supply amount of the cooling gas during the cooling process. Specifically, if the substrate S subjected to the heating process is present in the second area A2, the controller 400 increases the amount of the inert gas supplied from the cooler 290 to the substrate S in the second area A2. The amount of the inert gas supplied in the second area A2 may be increased by increasing the amount of the inert gas produced by the third gas source 294. Alternatively, the amount of the inert gas supplied in the second area A2 may be increased by reducing the amount of the inert gas supplied from the cooler 290 not located in the second area A2.

Further, the controller 400 may control the cooler 290 to be operated after the substrate S is moved to the second area A2. That is, the controller 400 may control the cooler 290 to be stopped if the substrate S is not present in the second area A2, and the cooler 290 to be operated if the substrate S is present in the second area A2.

In this embodiment, the controller 400 controls the movement operation to be performed if the end time of the substrate-processing process is earlier than or equal to the end time of cooling process. In other words, the controller 400 controls the movement operation to be performed if the end time of the cooling process is later than the end time of the substrate-processing process, or if the end time of the cooling process and the end time of the substrate-processing process are substantially equal to each other.

The controller 400 may be able to set the time for the substrate-processing process so that the heating state of the substrate S during the substrate-processing process is substantially the same as the heating state of the substrate S during the substrate-processing process for another lot. The expression “substantially the same” refers to, for example, a range of approximately ±10 degrees C.

If the cooling process continues in the second area A2 after the movement operation, the controller 400 may control the processed substrate S to wait in the first area A1.

Further, the controller 400 may control the substrate S, which has been subjected to the cooling process, to wait in the first area A1 if the loading of a new substrate S onto the boat 240 in the third area A3 is not completed after the movement operation. In addition, the controller 400 may control the substrate S, which has been subjected to the substrate-processing process, to wait in the first area A1 while a new substrate S is loaded onto the boat 240 that has been moved to the third area A3.

Further, the controller 400 may control the boat 240 to not be present in the first area A1 during at least a part of the time during which the substrate S is subjected to a heating process.

### (2) Substrate-Processing Process

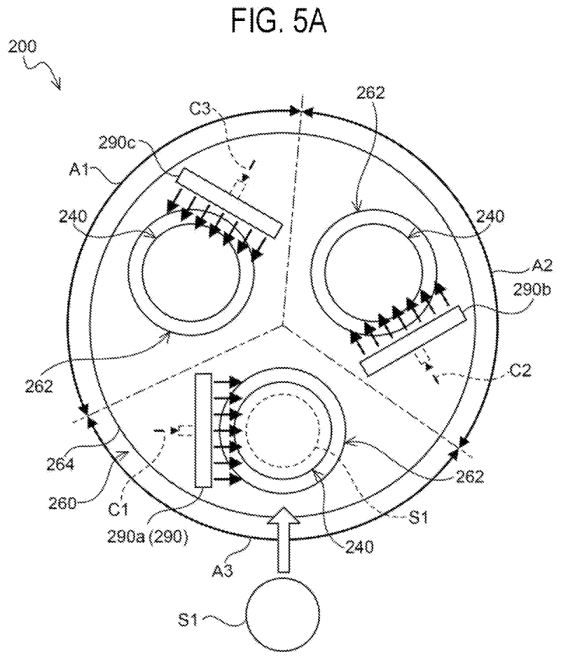

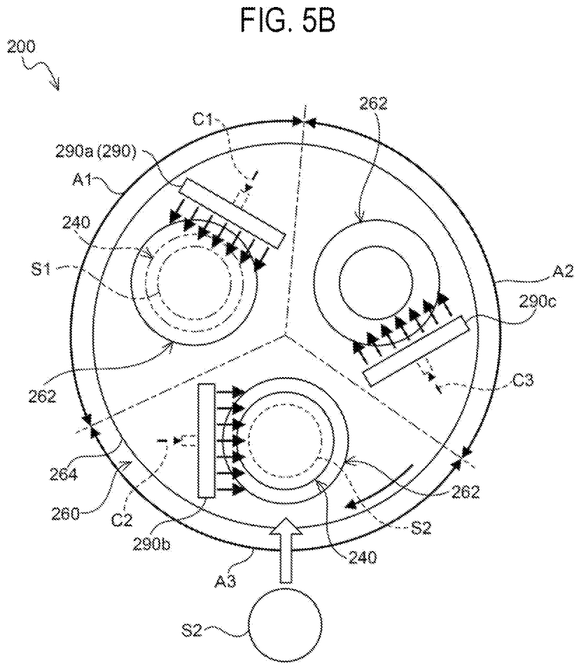

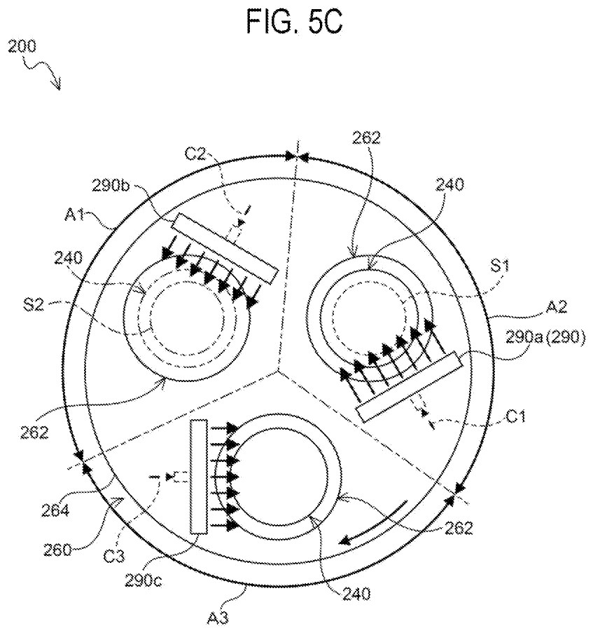

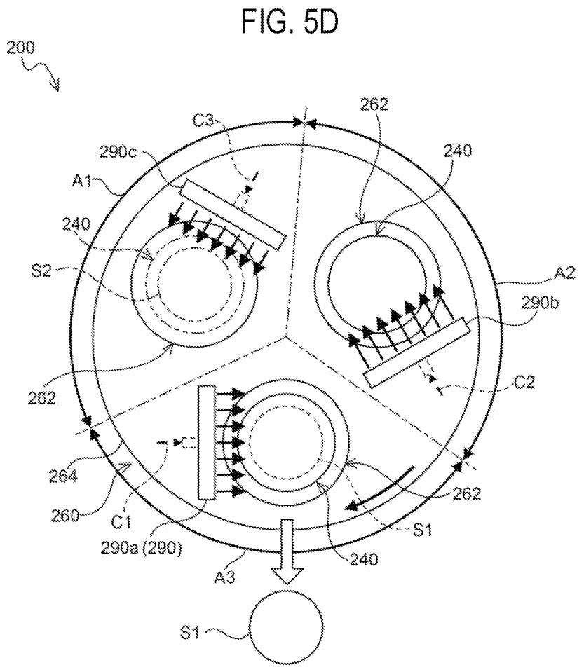

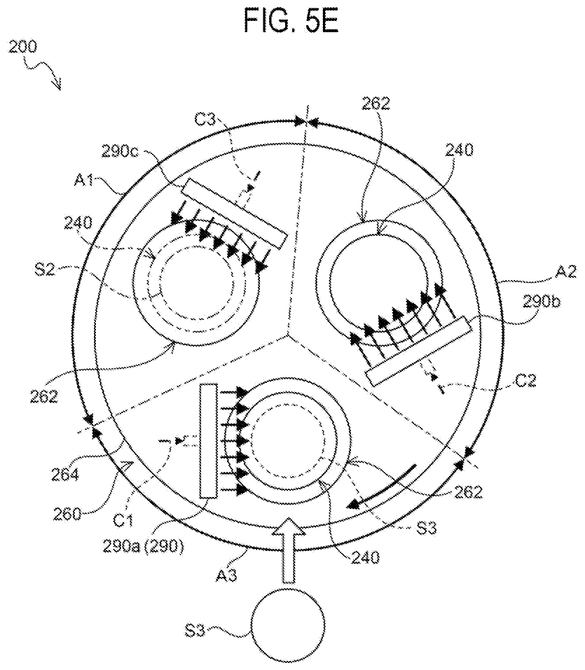

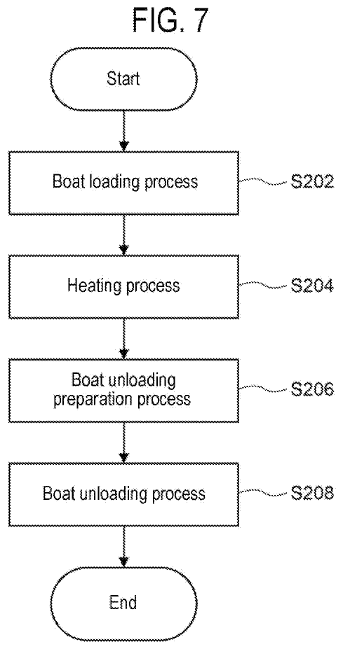

Next, the substrate-processing process will be described with reference to FIGS. 5A to 5E and FIG. 7. As one process performed in the substrate processing apparatus, a process of processing the substrate S using the substrate processing apparatus 100 including the above-described configuration will be described. In the following description, the operation of each part constituting the substrate processing apparatus is controlled by the controller 400.

First, as shown in FIG. 5A, the substrate S is delivered from the transfer chamber 140 to the boat 240 in the third area A3 of the delivery chamber 270 using the transfer robot 150. In this regard, the substrate S to be delivered to the boat 240 is designated by reference sign S1 for the sake of convenience.

Next, as shown in FIG. 5B, due to the rotation (clockwise rotation in FIG. 5B) of the revolution part 260, the boat 240 supporting the substrate S1 revolves from the third area A3 to the first area A1, and the boat 240 not supporting a substrate revolves from the second area A2 to the third area A3. In this case, the substrate S2 is transferred by the transfer robot 150 from the transfer chamber 140 to the boat 240 that has moved to the third area A3 and does not support a substrate.

### (Boat Loading Process S202)

If the boat 240 supporting the substrate S1 moves to the first area A1, the boat 240 is moved up while being supported by the boat elevator 274. The boat 240 is then accommodated in the process chamber 210. That is, in the boat loading step S202, the boat 240 located in the first area A1 is loaded into the process chamber 210.

### (Heating Step S204)

The boat 240 accommodated in the process chamber 210 is heated. That is, the substrate S1 mounted on the boat 240 is subjected to a heating process, and a film is formed thereon.

### (Boat Unloading Preparation Process S206)

Next, preparation for unloading the boat 240 from the process chamber 210 is started. Specifically, the pressure between the process chamber 210 and the delivery chamber 270 is regulated. Once the pressure is regulated, the preparation for unloading the boat 240 is completed. Further, the end time of the boat unloading preparation step S206 is the end time of the substrate-processing process to the substrate S.

### (Boat Unloading Process S208)

If the preparation for unloading the boat is completed, the boat 240 is unloaded from the process chamber 210 by the boat elevator 274 and is delivered to the boat support 262 on the first area A1 of the revolution part 260.

As shown in FIG. 5C, the boat 240 unloaded from the process chamber 210 is then revolved from the first area A1 to the second area A2 due to the rotation of the revolution part 260. The boat 240 that has moved to the second area A2 is cooled by an inert gas sent from the cooler 290.

On the other hand, the boat 240 supporting the substrate S2 is moved from the third area A3 to the first area A1 due to the rotation of the revolution part 260 and is moved up while being supported by the boat elevator 274. The boat 240 is then accommodated in the process chamber 210, and a substrate-processing process including a heating process is started.

The controller 400 selects either a revolution operation in which the substrate S1 is revolved by the revolution part 260 from the second area A2 to the third area A3 located adjacent to the transfer chamber 140 and arranged in the delivery chamber 270, or a movement operation in which the substrate S1 is moved from the process chamber 210 to the first area A1, according to the difference between the end time of the substrate-processing process including the heating process and the end time of the cooling process. In this embodiment, if the end time of the cooling process is earlier than the end time of the substrate-processing process, the controller 400 controls the revolution operation to be performed. Furthermore, if the end time of the substrate-processing process is earlier than or equal to the end time of the cooling process, the controller 400 controls the movement operation to be performed. In this embodiment, as shown in FIG. 5D, the cooling process is completed earlier than the substrate-processing process. Therefore, the boat 240 supporting the substrate S1 subjected to the cooling process is moved to the third area A3. Then, in the third area A3, the processed substrate S1 is unloaded from the boat 240 by the transfer robot 150.

Next, as shown in FIG. 5E, the transfer robot 150 transfers a new substrate S3 to the boat 240 from which the substrate S1 was taken out. After the transfer of the substrate S3 to the boat 240 is completed, the boat 240 supporting the substrate S3 waits in the third area A3 until the substrate-processing process for the boat 240 supporting the substrate S2 is completed. In the substrate processing apparatus 100 according to this embodiment, since the end time of the cooling process is earlier than the end time of the substrate-processing process, the unloading of the substrate S1 and the loading of the substrate S3 is performed until the substrate-processing process to the substrate S2 is completed. Therefore, the substrate processing apparatus 100 can reduce the excess waiting time of the substrate S as compared with, for example, a case where the substrate S1 is cooled or allowed to wait in the second area A2 until the substrate-processing process to the substrate S2 is completed. On the other hand, if the end time of the substrate-processing process is earlier than or equal to the end time of the cooling process, the movement operation is performed to move the substrate S1 from the process chamber 210 to the first area A1. Therefore, it is possible to reduce the excess waiting time for the substrate S and to suppress overheating of the substrate S2 within the process chamber 210.

Next, the operation of this embodiment will be described. In this embodiment, the controller 400 controls the revolution operation in which the substrate S2 is revolved by the revolution part 260 from the second area A2 to the third area A3, or the movement operation in which the substrate S1 are moved from the process chamber 210 to the first area A1, where the revolution operation or the movement operation is to be performed according to the difference between the end time of the substrate-processing process to the substrate S2 in the process chamber 210 and the end time of the cooling process to the substrate S1 in the second area A2. Therefore, the revolution operation of the substrate S can be set based on the difference between the end time of the heating process and the end time of the cooling process. Accordingly, as described above, the excess waiting time for the substrate S can be reduced. As a result, the processing throughput in the substrate-processing process can be improved.

In this embodiment, if the end time of the cooling process is earlier than the end time of the substrate-processing process, the controller 400 controls the revolution operation to be performed. Therefore, if the cooling process time is shorter than the substrate processing time, the cooled substrate can be unloaded without waiting for the completion of the substrate-processing process.

In this embodiment, the controller 400 controls the revolution operation to be performed if the time required for the substrate to move from the second area A2 to the third area A3 is smaller than the difference between the end times. Therefore, if the total time of the cooling processing time and the rotation time is shorter than the substrate processing time, the cooled substrate can be unloaded without waiting for the completion of the substrate-processing process.

In this embodiment, the controller 400 controls the revolution operation to be performed if there is no substrate to be newly subjected to the heating process. Therefore, if there is no substrate to be newly processed, the cooled substrate can be unloaded without waiting for the completion of the substrate-processing process.

In this embodiment, if there is no substrate waiting in the second area A2, the controller 400 controls the supply amount of the cooling gas to be set to be smaller than the supply amount of the cooling gas during the cooling process.

In this embodiment, the controller 400 moves the substrate, which has been moved from the process chamber 210 to the first area A1, and to the second area A2. Therefore, a new substrate can be loaded into the process chamber 210 without waiting for the cooling of the substrate subjected to the heating process.

In this embodiment, the controller 400 controls the cooler 290 to be operated after the substrate is moved to the second area A2. Therefore, the heat-process substrate can be cooled, and a new substrate can be loaded into the process chamber without delay, and thus it is possible to improve the processing throughput.

In this embodiment, the controller 400 controls the movement operation to be performed if the end time of the substrate-processing process is earlier than or equal to the end time of the cooling process. Therefore, if the substrate-processing process and the cooling process are performed almost simultaneously, or if the substrate-processing process is completed early, the heating process time for the substrate S in the process chamber 210 can be made constant among a plurality of lots.

In this embodiment, a resistance heater is used as the heater 214. Thus, it is difficult for the resistance heater to lower the temperature sharply even if it is turned off. Therefore, by performing the movement operation, the heating process time can be made constant between lots.

The substrate-processing process in this embodiment includes a loading process, a heating process, and a movement preparation process. Therefore, the time from the loading process to the movement preparation process, which is affected by the heater 214, can be made constant among lots.

The loading process in this embodiment is performed in a state in which the inside of the process chamber 210 is heated. Therefore, even if the substrate is loaded into the process chamber 210 in a preheated state, the heating process time can be made constant among lots.

The end time of the substrate-processing process in this embodiment is the time at which the movement preparation process ends. Therefore, by aligning the end times of the heating processes of the substrate-processing process, the heating process time can be made constant among lots.

The time of the substrate-processing process may be set so that the heating state of the substrate of one lot in the substrate-processing process according to this embodiment is substantially the same as the heating state of the substrate of another lot in the substrate-processing process. Therefore, by aligning the heating states of the substrate-processing process between lots, it is possible to make the heating process states constant.

If the cooling process continues after the movement operation, the controller 400 according to this embodiment controls the substrate S to wait in the first area A1 so that there is no need to stop the cooling process. Accordingly, there is no need to take a startup time to start the cooling process, and thus it is possible to improve the overall throughput.

In this embodiment, if the mounting of a new substrate onto the boat 240 in the third area A3 is not completed after the movement operation, the cooled substrate is controlled to wait in the first area A1. In this case, since the operation of mounting a new substrate in the third area A3 is not stopped midway, the adjustment time for starting the mounting process (the opening and closing of the gate valve 146 between the third area A3 and the transfer chamber 140, the vertical movement of the boat 240, and the like) is redundant, and thus it is possible to improve the overall throughput.

In this embodiment, while a new substrate is mounted onto the boat 240 that has been moved to the third area A3, the cooled substrate is controlled to wait in the first area A1. In this case, since the operation of mounting a new substrate onto the boat 240 in the third area A3 is not be stopped midway, the adjustment time for starting the mounting process (the opening and closing of the gate valve 146 between the third area A3 and the transfer chamber 140, the vertical movement of the boat 240, and the like) is redundant, and thus it is possible to improve the overall throughput.

In this embodiment, the boat may be controlled to not be present in the first area A1 during at least a part of the time during which the substrate is subjected to the heating process. In this case, while the substrate is being subjected to the heating process, the first area A1 may also be affected by heat. However, since the boat 240 is not present, it is possible to suppress excessive influence of heat.

### Other Embodiments

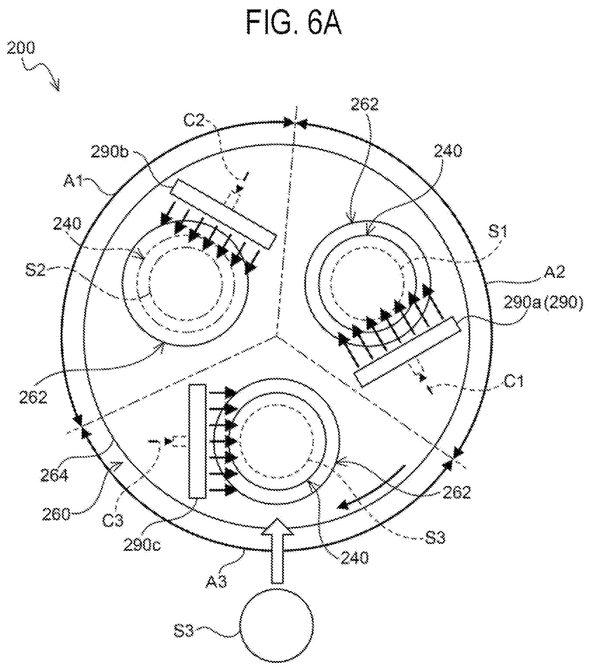

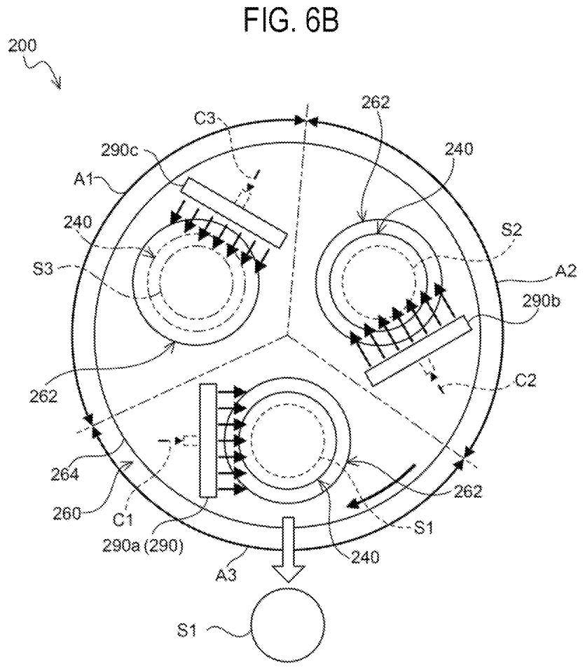

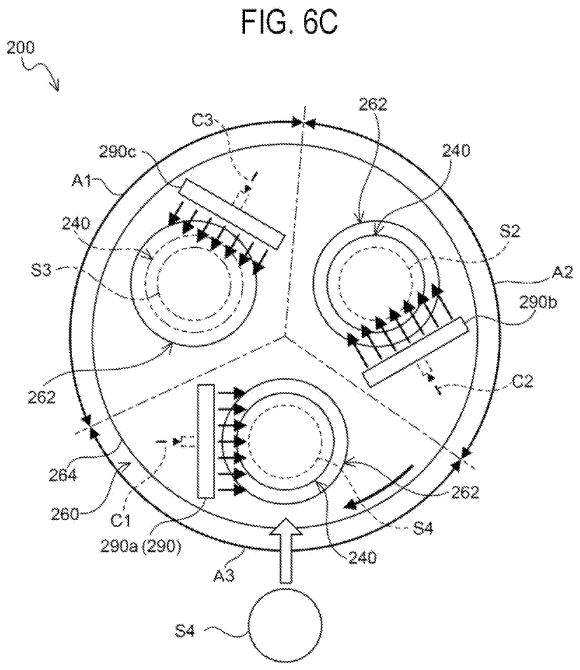

In the embodiment shown in FIGS. 5A to 5E, the apparatus is operated in a state in which the substrates S are mainly mounted on two of the three boats 240. However, the present disclosure is not limited to this configuration. For example, as shown in FIGS. 6A, 6B and 6C, the substrates S may be mounted on all three boats 240. FIG. 6A shows a step of loading the substrate S3 onto the boat 240, which does not support the substrate, after loading the substrate S2 onto the boat 240 in FIG. 5B. At this time, the substrate S1 is cooled in the second area A2, and the substrate S2 is accommodated and processed in the process chamber 210 in the first area A1. Thereafter, as shown in FIG. 6B, the substrate S2 is taken out from the process chamber 210, moved to the second area A2, and cooled. The substrate S3 is moved to the first area A1 and is accommodated and processed in the process chamber 210. The substrate S1 is moved to the third area A3 and is unloaded. Then, as shown in FIG. 6C, the substrate S1 is loaded onto the boat 240 from which the substrate S1 was unloaded.

Further, although the example in which one reactor 200 is used as the substrate processing apparatus 100 has been described, the present disclosure is not limited thereto. For example, a plurality of reactors 200 may be connected to the transfer chamber 140. In this case, substrate-processing processes for the substrates S can be performed in parallel using the plurality of reactors 200. Further, each of the plurality of reactors 200 may be an apparatus that performs different substrate-processing processes. In this case, after the substrate-processing process is performed in the first reactor 200, other substrate-processing process may be performed in the next reactor 200.

For example, in each of the embodiments described above, there has been described the case where in the film-forming process performed by the substrate processing apparatus, a SiN film is formed on the substrate S by using the hexachlorodisilane (HCDS) gas as the first-element-containing gas (first gas), and using the ammonia (NH₃) gas as the second-element-containing gas (second gas). However, the present disclosure is not limited thereto. That is, the processing gases used in the film-forming process are not limited to the HCDS gas, the NH₃ gas, and the like. Other types of gases may be used to form other types of thin films. Furthermore, three or more types of processing gases may be used. In addition, the first element may be various elements such as titanium (Ti), zirconium (Zr), and hafnium (Hf), instead of Si. Moreover, the second element may be, for example, nitrogen (N) instead of H.

Other embodiments of the present disclosure will be disclosed below.

A substrate processing apparatus, comprising:
a process chamber where a substrate-processing process including a heating process to a substrate is capable of being performed;
a boat configured to support the substrate;
a revolution part including a plurality of boat supports configured to support the boat, and capable of revolving the boat supports;
a delivery chamber including a first area arranged below the process chamber, a second area where the substrate after the heating process is capable of waiting, and a third area where the substrate is capable of being delivered to and from an adjacent transfer chamber, among areas above the revolution part;
a cooler capable of performing a cooling process to the substrate in the second area; and
a controller capable of controlling a revolution operation of revolving the substrate from the second area to the third area by the revolution part, or a movement operation of moving the substrate from the process chamber to the first area, such that the revolution operation or the movement operation is to be performed depending on a difference between an end time of the substrate-processing process to the substrate in the process chamber and an end time of the cooling process to the substrate in the second area,
wherein the controller is configured to:
(A) control the revolution part so as not to subject the boat to the revolution operation if the difference between the end time of the substrate-processing process in the process chamber and the end time of the cooling process in the delivery chamber is within a predetermined range,
(B) control the cooling process to be stopped if the difference between the end time of substrate processing in the process chamber and the end time of cooling processing in the transfer chamber is within a predetermined range;
(C) control the revolution part so as not to allow the boat to pass through the second area during at least a part of the time during which the substrate is subjected to the heating process; or
(D) control the revolution part so as to so allow the boat to wait in the first area or the third area during at least a part of the time during which the substrate is subjected to the heating process.

According to the present disclosure in some embodiments, it is possible to provide a technique capable of reducing the excess waiting time of a substrate in a substrate-processing process.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a process chamber where a substrate-processing process including a heating process to a substrate is capable of being performed;
a boat configured to support the substrate;
a revolution part including a plurality of boat supports configured to support the boat, and capable of revolving the boat supports;
a delivery chamber including a first area arranged below the process chamber, a second area where the substrate after the heating process is capable of waiting, and a third area where the substrate is capable of being delivered to and from an adjacent transfer chamber, among areas above the revolution part;
a cooler capable of performing a cooling process to the substrate in the second area; and
a controller capable of controlling a revolution operation of revolving the substrate from the second area to the third area by the revolution part, or a movement operation of moving the substrate from the process chamber to the first area, such that the revolution operation or the movement operation is to be performed depending on a difference between an end time of the substrate-processing process to the substrate in the process chamber and an end time of the cooling process to the substrate in the second area.

2. The apparatus of claim 1, wherein the controller is configured to control the revolution operation to be performed if the end time of the cooling process is earlier than the end time of the substrate-processing process.

3. The apparatus of claim 1, wherein the controller is configured to control the revolution operation to be performed if a time required to move from the second area to the third area is smaller than the difference between the end times.

4. The apparatus of claim 1, wherein the controller is configured to control the revolution operation to be performed if a substrate to be newly subjected to the heating process is not present.

5. The apparatus of claim 1, wherein the cooling process is configured to supply a cooling gas to the substrate waiting in the second area, and
wherein the controller is configured to control a supply amount of the cooling gas to be set as smaller than a supply amount of the cooling gas during the cooling process, if the substrate is not waiting in the second area.

6. The apparatus of claim 1, wherein the substrate moved from the process chamber to the first area is then moved to the second area.

7. The apparatus of claim 6, wherein the controller is configured to control the cooler to be operated after the substrate is moved to the second area.

8. The apparatus of claim 1, further comprising:
a heater configured to heat the process chamber,
wherein the controller is configured to control the movement operation to be performed if the end time of the substrate-processing process is earlier than or equal to the end time of the cooling process.

9. The apparatus of claim 8, wherein the heater includes a resistance heater.

10. The apparatus of claim 8, wherein the substrate-processing process includes:
a loading process of loading the substrate into the process chamber;
a heating process of heating the substrate in the process chamber; and
a movement preparation process of preparing to move the substrate from the process chamber to the delivery chamber, after the heating process.

11. The apparatus of claim 10, wherein the loading process is performed in a state in which an inside of the process chamber is heated.

12. The apparatus of claim 10, wherein the end time of the substrate-processing process is a time at which the movement preparation process ends.

13. The apparatus of claim 1, wherein a time of the substrate-processing process is settable so that a heating state of the substrate of one lot in the substrate-processing process is substantially the same as a heating state of the substrate of another lot in the substrate-processing process.

14. The apparatus of claim 1, wherein the controller is configured to control the substrate to wait in the first area if the cooling process continues after the movement operation.

15. The apparatus of claim 1, wherein the controller is configured to control the substrate subjected to the substrate-processing process to wait in the first area if the mounting of a new substrate onto the boat in the third area is not completed after the movement operation.

16. The apparatus of claim 1, wherein the controller is configured to control the substrate subjected to the substrate-processing process to wait in the first area while a new substrate is mounted onto the boat that has been moved to the third area.

17. The apparatus of claim 1, wherein the controller is configured to control the boat to not be present in the first area during at least a part of a time during which the substrate is subjected to the heating process.

18. A method of processing a substrate, comprising:
performing a substrate-processing process including a process of heating the substrate mounted onto a boat in a process chamber arranged above a first area of a delivery chamber, and a cooling process of cooling the substrate mounted on the boat in a second area of the delivery chamber; and
revolving the substrate by a revolution part from the second area to a third area adjacent to a transfer chamber and arranged in the delivery chamber, or moving the substrate from the process chamber to the first area, depending on a difference between an end time of the substrate-processing process and an end time of the cooling process.

19. A method of manufacturing a semiconductor device, wherein substrate are processed by the method of claim 18.

20. A non-transitory computer-readable recording medium storing a program that causes, by a computer, a substrate processing apparatus to perform a process comprising:
performing a substrate-processing process including a process of heating a substrate mounted onto a boat in a process chamber arranged above a first area of a delivery chamber, and a cooling process of cooling the substrate mounted on the boat in a second area of the delivery chamber; and
revolving the substrate by a revolution part from the second area to a third area adjacent to a transfer chamber and arranged in the delivery chamber, or moving the substrate from the process chamber to the first area, depending on a difference between an end time of the substrate-processing process and an end time of the cooling process.
